(19) United States
(12) Patent Application Publication
(10) Pub. No.: US 2019/0244891 A1
(43) Pub. Date: Aug. 8, 2019

(54) HARDWARE FALLBACK FOR NON-CONFIGURABLE FEATURES

(71) Applicant: Seagate Technology LLC, Cupertino, CA (US)

(72) Inventors: Vikrant Anand Joshi, Pune (IN); Omkar Shrikant Bhatkhande, Pune (IN); Sachin Shivanand Bastimane, Pune (IN)

(21) Appl. No.: 15/887,230

(22) Filed: Feb. 2, 2018

(51) Int. Cl. H01L 23/525; H01L 23/528; H01L 23/522; H01L 21/768; H01L 21/66

(52) U.S. Cl. CPC H01L 23/525; H01L 23/528; H01L 23/57; H01L 21/76895; H01L 22/20; H01L 23/5226

(57) ABSTRACT

An integrated circuit chip with a fallback option in case of feature implementation failure includes providing metal layers on an integrated circuit chip and coupling non-programmable features to upper metal layer(s) of the circuit chip. A method further provides correcting at least one of the plurality of non-programmable features in case of implementation failure by changing the upper metal layer.

### SUMMARY

An integrated circuit of the disclosure may include a plurality of metal layers and a plurality of features coupled to the plurality of metal layers. A plurality of non-configurable features of the plurality of features may be coupled to upper layers (e.g., readily accessible layers) of the plurality of metal layers to provide a hardware fallback option for the non-configurable features in case of implementation failure.

One method of programming an integrated circuit chip with a plurality of metal layers includes providing a plurality of programmable features and a plurality of non-programmable or non-configurable features on the plurality of metal layers, coupling at least one of the non-programmable features to an upper metal layer of the plurality of layers, and testing the plurality of programmable and non-programmable features. The method further provides bypassing any non-programmable features having an implementation failure, verifying the programmable features, and correcting the non-programmable features.

A method of manufacturing an integrated circuit includes providing a plurality of metal layers and coupling at least one of a plurality of non-programmable or non-configurable features to an accessible feature metal layer of the plurality of metal layers.

This summary is not intended to describe each disclosed embodiment or every implementation of the hardware fallback for non-configurable features disclosed herein. Many other novel advantages, features, and relationships will become apparent as this description proceeds. The figures and the description that follow more particularly exemplify illustrative embodiments.

### BRIEF DESCRIPTION OF THE DRAWINGS

FIG. 1 is a side view diagram of metal layers according to an embodiment of the present disclosure.

FIG. 2 is a diagram of metal layers according to an embodiment of the present disclosure.

FIG. 3 illustrates a flow diagram of an embodiment of the present disclosure.

FIG. 4 illustrates a flow diagram of another embodiment of the present disclosure.

FIG. 5 illustrates a flow diagram of yet another embodiment of the present disclosure.

FIG. 6 is an illustration of a metal layer connection according to an embodiment of the present disclosure.

### DETAILED DESCRIPTION

The present disclosure generally pertains to integrated circuit design. More specifically, the present disclosure pertains to providing features on specific metal layers of an integrated circuit chip.

Integrated circuits commonly embed cores based on a system-on-chip (SoC) design. An SoC stitches together multiple cores to provide functionality for a variety of applications. Once an SoC is designed, the design may be implemented in the form of a silicon chip and various features are tested for functionality. When features are implemented for the first time in the SoC there is the possibility they will not function according to definition. Most features are configurable, and if a feature has an implementation failure and is configurable, it may be reprogrammed through configuration registers to allow any remaining features to be verified. Features that are not programmable are altered by making a physical change to a base or metal layer of the SoC.

Embodiments described herein relate to a technique of connecting non-programmable features of a system-on-chip (SoC) device to upper metal layers of the SoC device when there is an issue (e.g., failure) with implementation of one or more of those non-programmable features. Many features of an SoC are configurable, and may be altered through programming in the case of issues with implementation. Features may be programmable by configuration registers, usually accessed by firmware, which may disable or enable a feature. However, certain features of an SoC are not programmable, and may be used in final operation, but not in testing. For example, when a new feature is being implemented in a chip design, the new and existing features may be verified before full production begins. Previously, some non-configurable features, such as power switches, were coupled to the base or lower levels of the SoC. However, to change a metal layer, first the layers above that layer are removed, the layer is replaced with a corrected layer, and then the upper layers are replaced. Thus, if a non-programmable feature fails during implementation, the feature layer and the upper metal layers are physically changed to correct the error, at the cost of time and money, in order to verify the remaining features.

For example, the SoC firmware typically does not have access to enable or disable a power switch feature during implementation. During power switch implementation, control may be passed to a power state machine to check the power state table and decide whether to enable or disable power switches. Since the control for the power switch lies inside the SoC, if there is an issue or bug with the implementation, the design will not function properly. Moreover, as changes to the power switch implementation are related to the control of power, there is no way to disable the logic properly while maintaining operation of the SoC, leaving the chip essentially dead and any remaining features unverifiable.

In another example, configuration registers are not given access to security logic control in order to prevent hacking through the firmware. Thus, if security logic fails during implementation, a change is made on the metal layer to correct the issue and allow the remaining features to be verified. Thus, power switch implementation and security logic are not programmable by configuration registers, and errors in their implementation would stop other features of the SoC from being verified.

If one or more of these non-programmable features do not function according to definition when being implemented for the first time, the SoC may not function, or may function in specific modes, such as a design-for-test (DFT) mode. When such implementation issues occur, a change in the device may be made. For programmable features of an SoC, the changes may be implemented with configuration register changes. However, for non-programmable features, changes are made by physically changing the metal layer. An engineering change order (ECO) may be issued to change a base layer or metal layer(s) of an SoC to alter features that cannot be altered by programming. However, embodiments of the present disclosure allow bypassing by a physical change to the metal layer to allow verification of the remaining features.

Chip fabrication comes in many forms and methods; however, a generalized process may use steps in the general categories of deposition, removal, patterning, and modification of electrical properties. Various chip layers may be built onto a wafer utilizing masks in a photolithographic process. Masks contain geometric shapes that correspond to the patterns of metal, oxide, or semiconductor layers that make up the components of an integrated circuit. Deposition is then used to deposit the material onto a wafer. The removal process may then include etching to remove the excess material and form the layer pattern on the chip. Modification of electrical properties may include processes such as doping and annealing. Often, a nonconducting layer is placed between chip layers and then a new mask layer is used to form the next chip layer, repeating the process.

If a non-programmable feature fails implementation, the chip is typically re-spun (e.g., refabricated) to correct the appropriate layer. The process may include stripping off each upper layer until the layer with the failed feature is reached and then fabricating a new layer by remasking, redepositing, and etching the new chip layer. This process is repeated for the layers removed to reach the failed feature layer. Thus, higher layers in a chip may use less time and money to replace than lower layers and allow a faster time to market.

Changing base or metal layer(s) takes time and ranges in cost from approximately thousands of dollars for upper metal layer(s), tens of thousands of dollars for intermediate layers, to hundreds of thousands of dollars for a lowermost metal layer. Depending on which metal layers are changed, the total cost and time for re-spin will change. Embodiments of the disclosure provide methods of connecting certain features to the upper metal layers of an SoC to reduce the cost and time to make changes in case of an issue with implementation of a non-configurable feature.

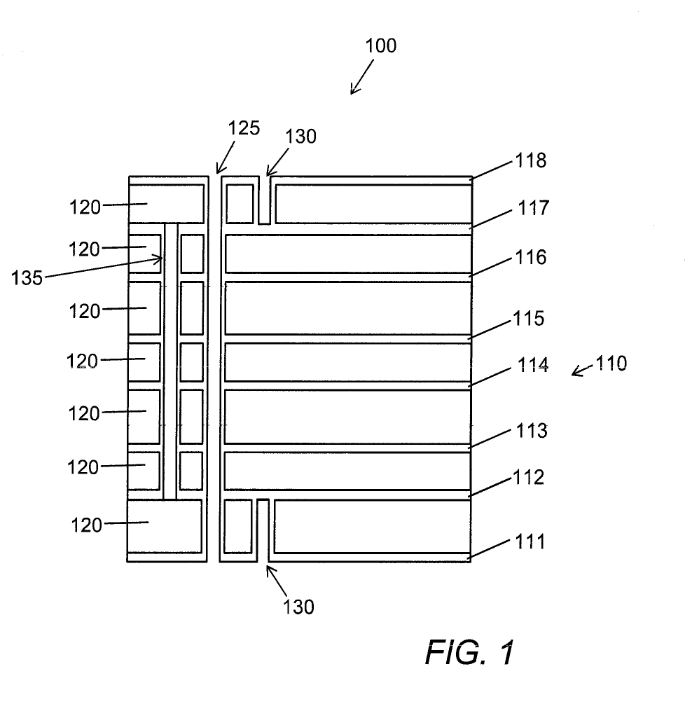

FIG. 1 illustrates a side view of a simplified diagram of stacked metal layers of an SoC. A chip 100 includes a plurality of metal layers 110 with nonconductive material 120 placed between them. Chip 100 also includes a plurality of vias, such as a through-hole via 125, a blind via 130, and a buried via 135. Vias provide electrical connections between layers on a physical electronic circuit and may be placed in various configurations within a three-dimensional chip. Chip 100 includes eight metal layers 110 separated by nonconductive material 120 where a first metal layer 111 (metal 1) is the lowest most layer and an eighth layer 118 (metal 8) is the top most layer. Via 125 connects the bottom layer (metal 1) 111 to the topmost metal layer metal 8 118. A blind via 130 connects an outer layer to one or more inner layers, such as from metal 1 111 to metal layer 112 (metal 2), or metal 8 118 to metal layer 117 (metal 7). A buried via 135 connects two or more inner layers but does not connect to an outer layer, such as from metal 2 112 to metal layer 117 (metal 7). However, chip 100 is exemplary only, and an SoC may have a plurality of metal layers with a variety of electrical connections and vias in different designs.

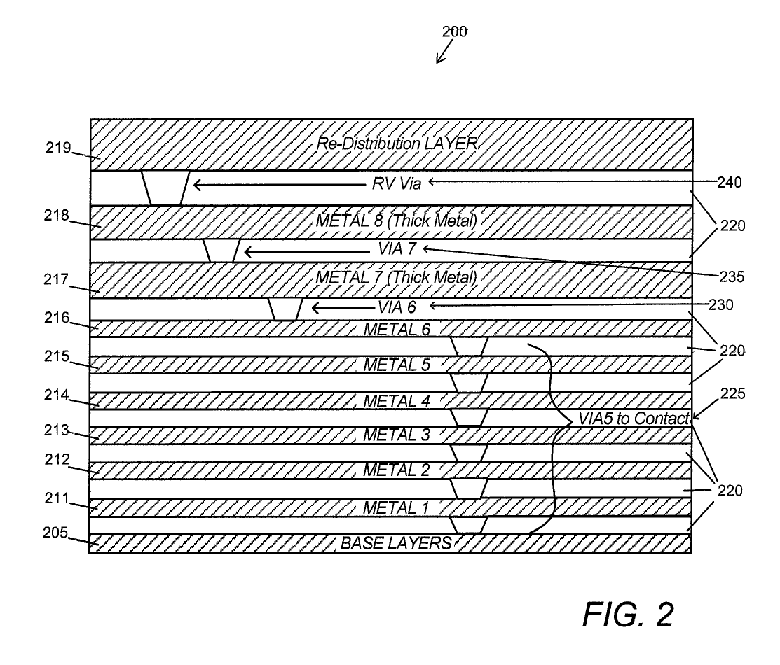

FIG. 2 illustrates a simplified diagram of stacked metal layers of an SoC of the present disclosure. A chip 200 includes eight metal layers separated by nonconductive layers 220. A lower metal layer, e.g., Metal 1, (211) through metal 6 (216) form lower and intermediate layers above base layer(s) 205 and may be coupled by a through hole via or a plurality of vias, e.g., via 5 (225). Metal 6 (216) is further coupled to upper metal layers with vias, such that metal 6 (216) is coupled with metal 7 (217) through via 6 (230), and metal 7 (217) is coupled with metal 8 (218) with via 7 (235). Finally, metal 8 (218) is coupled to re-distribution layer (RDL) 219 through RV via 240. The RDL 219 is the topmost layer on a die and may be used to couple die pins to package pins; the RV via 240, e.g., redistribution via, couples the RDL 219 to the next lower metal layer. Although FIG. 2 describes upper metal layers 217, 218 as thick metal layers, the layers need not be so limited. Further, one skilled in the art will recognize that vias may be provided throughout the stacked layers of a three-dimensional chip in various configurations. Still further, it should be understood that the number of metal layers shown is exemplary, and that more or fewer layers may be used without departing from the scope of the disclosure.

As described above, the upper metal layers, such as metal 7 and metal 8, are much less expensive to change than metal layers buried further down the SoC. For example, metal 7 and metal 8 layers may cost on the order of thousands of dollars to change compared to the hundreds of thousands of dollars to change a base or lower layer. Thus, the cost for re-spin will vary with which metal layer that is changed.

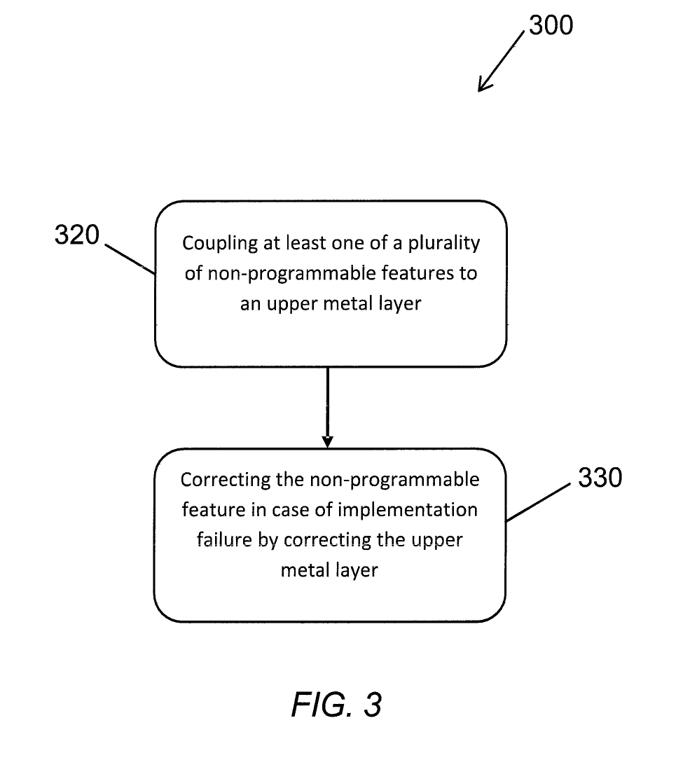

FIG. 3 illustrates a simplified method 300 of programming an integrated circuit having a plurality of metal layers, non-programmable features, and programmable features, by for example, providing a fallback option in case of implementation failure of a non-programmable feature of the integrated circuit. Method 300 includes coupling at least one of the non-programmable features to an upper metal layer 320 of the plurality of metal layers, and correcting the non-programmable feature in case of implementation failure by changing the metal layer 330. Although this method is simplified, it will be appreciated by those skilled in the art that the teachings of this method may be applied in different embodiments without departing from the scope of the present disclosure.

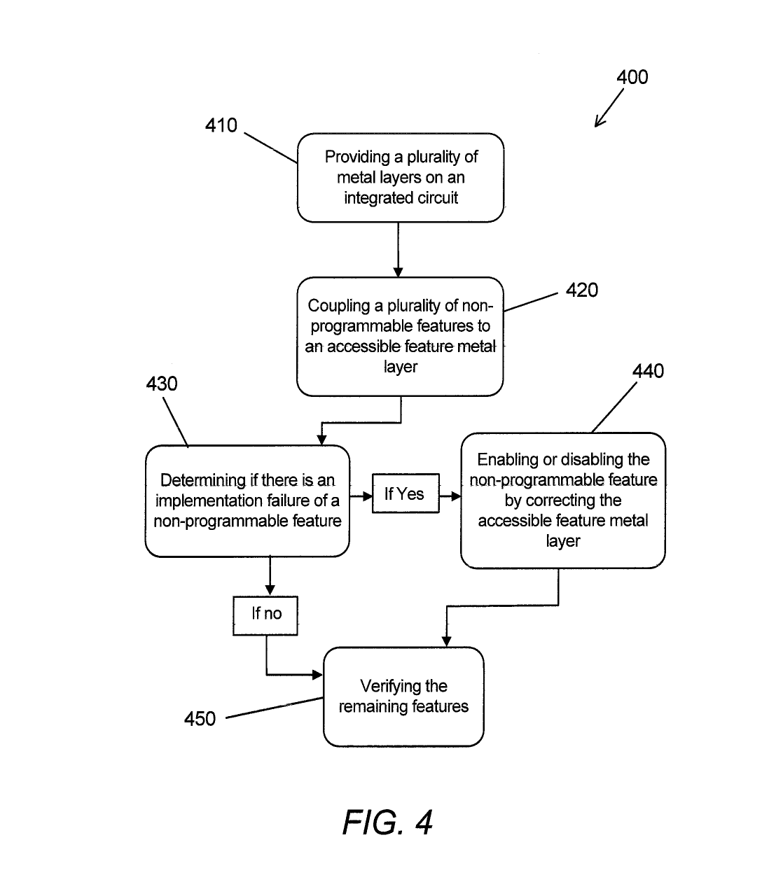

FIG. 4 illustrates another embodiment of a method of manufacturing an integrated circuit in case of a non-programmable feature implementation failure. Method 400 includes providing a plurality of metal layers on an integrated circuit 410 and coupling the non-programmable features to an accessible feature metal layer 420 of the plurality of metal layers. Upon determining if there is an implementation failure of a non-programmable feature 430, the feature may be corrected by changing the accessible feature metal layer to bypass the issue, such as by enabling or disabling the feature. The remaining features on the chip may be verified 450 once the failure has been bypassed or if there was no implementation failure.

In one embodiment regarding power switch implementation, power signals may be brought to an uppermost metal layer(s) of a plurality of metal layers where power switches are connected. If a failure is found during power switch implementation, the power switch is bypassed. Once the power switch has been bypassed, the remaining features may be verified. In one example, a via may be used to bypass the power switches and connect directly to the power on the chip. Here, changing the upper metal layer would change the upper via, such as via 7 or via 8 of FIG. 2, to bypass the power switches and feed power directly to the cells. Thus, if metal layer(s) 7 and or 8 are the most accessible, time, and or cost-effective metal layers to change, the non-programmable power switches may be connected to metal layer(s) 7 and/or 8 as a fallback option in case there is an issue with power switch implementation. Then, if there is an issue (e.g., failure) during implementation, following verification of the remaining features, the chip may be re-spun (e.g., refabricated) to change the specific metal layer with the power switches, and power nets may then be directly connected to the always-on power (e.g., main power located on the base layer). In this embodiment, the upper layer is stripped from the chip, and remasked to fabricate the new layer.

In an embodiment regarding security features that are not programmable through firmware, the control signal for enabling and disabling the security features will be brought to an uppermost metal layer(s) where network ties (e.g., components that allow for shorting of various networks in a design) are located. For example, the control signal for enabling and disabling a security feature may be coupled to an upper metal layer with the network ties, e.g., tie 0 or tie 1, for disabling the control signal, then if there are issues (e.g., failure) in a security feature's implementation, the control signal may be disconnected from the circuit and connected to the network tie. An ECO may be issued to change the metal layer the feature is connected to in order to disconnect the control signal from the circuit and connect to the network tie. Once the security feature has been bypassed, the remaining features may be verified. Therefore, if metal layer(s) 7 and/or 8 are the most accessible, time and or cost-effective metal layers to change, the non-programmable security feature may be connected to metal layer(s) 7 and or 8 as a fallback option in case there is an issue with the security feature's implementation. Thus, the top layer is stripped from the chip and a new mask is used to fabricate a new layer in case of implementation failure.

Although examples have described power switches and security features as non-programmable features, various power signals, control signals, and other features may be coupled on the same layer and or to an upper layer(s) to reduce the cost and time when physically changing a non-configurable feature. In one example of the present disclosure, control signal connections may be brought to a top metal level which may not be otherwise needed but which allows easy access in case a change is requested.

In a second example, a power mesh comprising power switches and power control logic may be built into an upper level, such that if there is an issue (e.g., failure) with its functionality it may be shorted with a via, such as by connecting to via 5 (225). Thus, coupling a power mesh to an upper metal layer allows power switches and power control logic that may have failures to be bypassed, and enables access to power on a lower metal or base layer. Similarly, another example of the present disclosure includes making various supply connections so that tracks supplying power may cross each other. By crossing the tracks supplying power, a via may then be changed to bypass, or short, a problematic function, such as a control switch or control circuit. By making these connections on an upper metal layer, the number of changes to the chip may be further reduced and simplified.

In another example, a design may include making provisions so that tie cell connections (e.g., tie 0 or tie 1) are also routed with control signals. By routing tie cell connections with control signals, any changes to be made in the metal layer in case of a failure would be minor. Re-routing these connections may then reduce the number of metal layers that would otherwise be removed and replaced in case a change is requested.

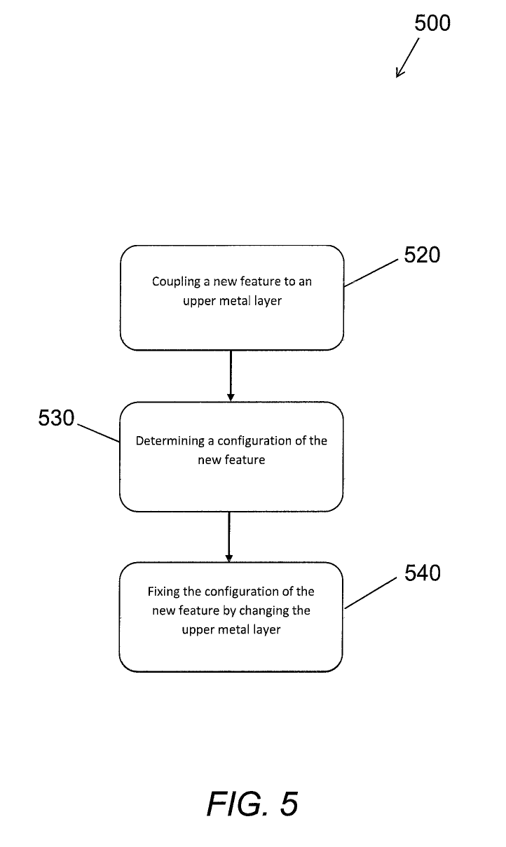

In another embodiment, a new feature may be introduced on an SoC for testing. FIG. 5 illustrates a method 500 of programming a new feature by providing a plurality of metal layers on an integrated circuit comprising coupling a new feature to an upper metal layer 520, determining a correct configuration of the new feature 530, and then fixing 540 the correct configuration of the new feature into the integrated circuit by changing the upper metal layer.

For example, a new feature, such as a frequency hopping feature, may be introduced on an SoC, but the configuration values may not be known. In this example, the feature may be placed on an accessible metal layer, such as an upper metal layer, but initially kept configurable through registers to enable testing and programming of different values on a physical chip. Once the new feature is functional and the correct configuration values are determined, an ECO may be issued to physically replace the upper layer and fix it with the determined configuration. Once the metal layer is corrected, the chip may than proceed to production. This embodiment provides great flexibility, and enables less cost, less risk, and less time to market when developing new features by allowing an accessible metal layer to be removed and replaced with a modified version.

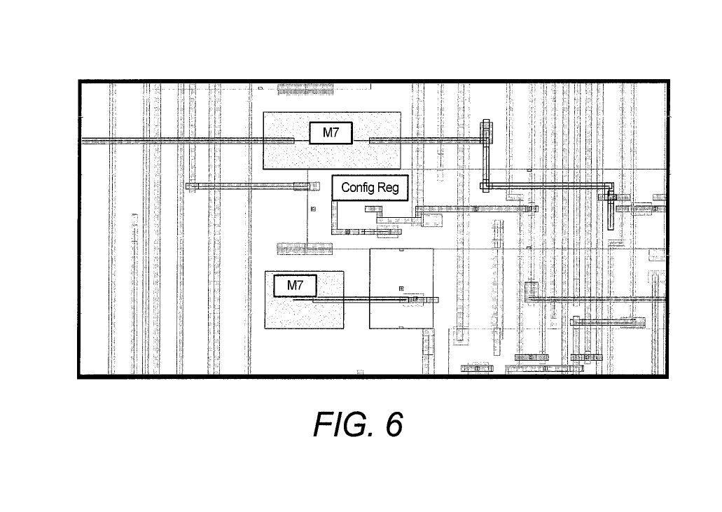

In the embodiments described above, and in similar embodiments with non-programmable or new features, if an issue with implementation is detected, the non-programmable features on upper metal layers bypassed and or disabled (e.g., enabled or disabled) to allow verification of other features. Once testing of other features is complete, the affected metal layer may be changed. Once the metal layer is changed, the other functional features and test features of the SoC may be tested. FIG. 6 illustrates an updated route bringing a feature to metal 7. Non-programmable features may be placed on a feature layer(s), and by keeping non-programmable features to a limited number of metal layers, the feature may be configured, e.g., by enabling or disabling the feature, by changing only the layer with the non-programmable feature. Further, by providing the non-programmable features on the uppermost layer(s), such as on metal layer(s) 7 and or 8 (e.g., metal layer 117 or metal layer 118), the time and cost of making physical changes to an SoC may be reduced. Therefore, a method for coupling non-programmable features to the upper metal layer(s) provides a less costly fallback option in case of implementation failure.

Although examples of non-programable features within an SoC have been disclosed in the application, embodiments are not limited to the particular applications or uses disclosed in the application. This disclosure, therefore, is illustrative only and changes may be made in detail in matters of structure, arrangement, and methods without departing from the scope of the present disclosure.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and therefore are not drawn to scale. Certain proportions within the illustrations may be exaggerated, while other proportions may be reduced. Accordingly, the disclosure and the figures are to be regarded as illustrative rather than restrictive.

Although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

In addition, in the foregoing Detailed Description, various features may be grouped together or described in a single embodiment for the purpose of streamlining the disclosure. This disclosure is not to be interpreted as reflecting an intention that the claimed embodiments employ more features than are expressly recited in each claim. Rather, as the following claims reflect, inventive subject matter may be directed to less than all of the features of any of the disclosed embodiments.

The above-disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

1. An integrated circuit comprising:
a plurality of metal layers; and
a plurality of features coupled to the plurality of metal layers, wherein the plurality of features includes a plurality of non-configurable features coupled to an upper metal layer of the plurality of metal layers.

2. The integrated circuit of claim 1, wherein the plurality of non-configurable features includes power switches or power signals.

3. The integrated circuit of claim 1, wherein the plurality of non-configurable features includes security features.

4. The integrated circuit of claim 1, wherein the plurality of non-configurable features includes operation signals.

5. A method of programming an integrated circuit chip having a plurality of metal layers, comprising:
providing a plurality of programmable features and a plurality of non-programmable features on the plurality of metal layers;
coupling at least one of a plurality of non-programmable features of the integrated circuit chip to an upper metal layer of the plurality of metal layers;
testing the plurality of programmable features and non-programmable features of the integrated circuit;
bypassing any non-programmable features having an implementation failure;
verifying the programmable features; and
correcting the non-programmable features having an implementation failure.

6. The method of claim 5, wherein correcting the non-programmable features having an implementation failure comprises changing the upper metal layer containing non-programmable features having the implementation failure.

7. The method of claim 5, wherein at least one of the plurality of non-programmable features are enabled by changing the upper metal layer.

8. The method of claim 5, wherein at least one of the plurality of non-programmable features are disabled by changing the upper metal layer.

9. The method of claim 5, wherein the plurality of metal layers comprises 8 metal layers and the upper metal layer comprises at least one of metal layer 7 or metal layer 8.

10. A method of manufacturing an integrated circuit chip, comprising:
providing a plurality of metal layers; and
coupling at least one of a plurality of non-programmable features to an accessible feature metal layer of the plurality of metal layers.

11. The method of claim 10, wherein at least one of the plurality of non-programmable features is enabled by changing the accessible feature metal layer.

12. The method of claim 10, wherein at least one of the plurality of non-programmable features is disabled by changing accessible feature metal layer.

13. The method of claim 10, wherein correcting the accessible feature metal layer further comprises removing and reforming the accessible feature metal layer with corrected features.

14. The method of claim 10, wherein the plurality of non-programmable features includes power switches or power signals.

15. The method of claim 10, wherein the plurality of non-programmable features includes security features.

16. The method of claim 10, wherein the plurality of non-programmable features includes operation signals.

17. The method of claim 10 and further comprising testing the features of the integrated circuit chip.

18. The method of claim 17, wherein testing further comprises bypassing any non-programmable features having an implementation failure and verifying programmable features.

19. The method of claim 18 and further comprising correcting the accessible feature metal layer for bypassed non-programmable features.

20. The method of claim 10, wherein the accessible feature metal layer comprises an upper metal layer of the plurality of metal layers.
